(19) United States
(12) Patent Application Publication
(10) Pub. No.: US 2024/0194488 A1
(43) Pub. Date: Jun. 13, 2024

(54) METHOD FOR MANUFACTURING MASK PATTERN AND METHOD FOR MANUFACTURING SEMICONDUCTOR DEVICE USING THE MASK PATTERN

(71) Applicant: SAMSUNG ELECTRONICS CO., LTD., Suwon-si (KR)

(72) Inventors: Ho Young LEE, Suwon-si (KR); Jong Doo Kim, Suwon-si (KR); Ju Yun Park, Suwon-si (KR)

(21) Appl. No.: 18/243,185

(22) Filed: Sep. 7, 2023

(30) Foreign Application Priority Data
Dec. 7, 2022 (KR) 10-2022-0170149

(51) Int. Cl. H01L 21/308; H01L 29/66

(52) U.S. Cl. CPC H01L 21/308; H01L 29/66439; H01L 29/66545

(57) ABSTRACT

A method for manufacturing a mask pattern includes forming a mold mask layer on a substrate. A pre-mold mask pattern that includes a first trench extending in a first direction is formed by etching the mold mask layer. The first trench has a first width in a second direction crossing the first direction. A mold mask pattern that includes a second trench connected to the first trench is formed by etching the pre-mold mask pattern. The second trench has a second width different from the first width in the second direction. The second trench is adjacent to the first trench in the first direction. A process mask pattern that fills the first and second trenches is formed in the mold mask pattern and disposed on the substrate. The mold mask pattern is removed and the process mask pattern remains disposed on the substrate after removing the mold mask pattern.

### CROSS-REFERENCE TO RELATED APPLICATION

This application claims priority under 35 U.S.C. 119 to Korean Patent Application No. 10-2022-0170149, filed on Dec. 7, 2022 in the Korean Intellectual Property Office, the disclosure of which is incorporated by reference in its entirety herein.

### 1. TECHNICAL FIELD

The present disclosure relates to a method for manufacturing a mask pattern and a method for manufacturing a semiconductor device using the mask pattern.

### 2. DISCUSSION OF RELATED ART

A multi-gate transistor is being developed as a scaling technique for increasing a density of a semiconductor device. A multi-gate transistor may include a multi-channel active pattern (e.g., a silicon body) of a fin or nano-wire shape that is formed on a substrate. A gate is then formed on a surface of the multi-channel active pattern.

Since the multi-gate transistor uses a three-dimensional channel, it is easy to scale the multi-gate transistor. Also, even though a gate length of the multi-gate transistor is not increased, the multi-gate transistor may increase a current control capability. In addition, a short channel effect (SCE) in which a potential of a channel region is affected by a drain voltage may be effectively suppressed.

### SUMMARY

A purpose of an embodiment of the present disclosure is to provide a method for manufacturing a mask pattern, which may increase corner rounding of a tapered pattern.

Another purpose of an embodiment of the present disclosure is to provide a method for manufacturing a semiconductor device using a mask pattern, which may increase corner rounding of a tapered pattern.

Purposes of embodiments of the present disclosure are not limited to the above-mentioned purposes. Other purposes and advantages of embodiments according to the present disclosure that are not mentioned may be understood based on following descriptions. Further, it will be easily understood that the purposes and advantages according to embodiments of the present disclosure may be realized using means shown in the claims and combinations thereof.

According to an embodiment of the present disclosure, a method for manufacturing a mask pattern includes forming a mold mask layer on a substrate. A pre-mold mask pattern that includes a first trench extending in a first direction is formed by etching the mold mask layer. The first trench has a first width in a second direction crossing the first direction. A mold mask pattern that includes a second trench connected to the first trench is formed by etching the pre-mold mask pattern. The second trench has a second width different from the first width in the second direction. The second trench is adjacent to the first trench in the first direction. A process mask pattern that fills the first and second trenches is formed in the mold mask pattern and disposed on the substrate. The mold mask pattern is removed and the process mask pattern remains disposed on the substrate after removing the mold mask pattern.

According to an embodiment of the present disclosure, a method for manufacturing a semiconductor device includes forming an upper pattern layer on a substrate. The upper pattern layer includes at least one channel layer and at least one sacrificial layer that are alternately stacked on the substrate. A mold mask layer is formed on the upper pattern layer. A first upper mold mask pattern is formed on the mold mask layer. The first upper mold mask pattern includes a first mold opening extending in a first direction. The first mold opening has a first width in a second direction crossing the first direction. A pre-mold mask pattern that includes a first trench is formed by etching the mold mask layer using the first upper mold mask pattern. A second upper mold mask pattern is formed on the pre-mold mask pattern. The second upper mold mask pattern includes a second mold opening extending in the first direction. The second mold opening has a second width different from the first width in the second direction. The second mold opening overlaps a portion of the first trench in a third direction that is a thickness direction of the substrate. A mold mask pattern that includes a second trench connected to the first trench is formed by etching the pre-mold mask pattern using the second upper mold mask pattern. A process mask pattern is formed in the mold mask pattern. The process mask pattern fills the first trench and the second trench. A lower pattern and an upper pattern structure extending in the first direction is formed by using the process mask pattern. The lower pattern and the upper pattern structure are formed by etching a portion of the substrate and the upper pattern layer.

According to an embodiment of the present disclosure, a method for manufacturing a semiconductor device includes forming an upper pattern layer on a substrate. The upper pattern layer includes at least one channel layer and at least one sacrificial layer that are alternately stacked on the substrate. A mold mask pattern is on the upper pattern layer. The mold mask pattern includes a connection trench extending in a first direction. The connection trench includes a first trench having a first width in a second direction crossing the first direction and a second trench having a second width in the second direction. A process mask pattern is formed in the mold mask pattern. The process mask pattern fills the connection trench. A lower pattern and an upper pattern structure that extend in the first direction are formed by using the process mask pattern after removing the mold mask pattern. The upper pattern structure includes at least one channel pattern and at least one sacrificial pattern that are alternately stacked on the lower pattern. A dummy gate electrode is formed on the upper pattern structure. The dummy gate electrode extends in the second direction. A source/drain pattern is formed on the lower pattern. The source/drain pattern is connected to the channel pattern. A sheet pattern connected to the source/drain pattern is formed by removing the sacrificial pattern after forming the source/drain pattern.

### BRIEF DESCRIPTION OF THE DRAWINGS

The above and other aspects and features of the present disclosure will become more apparent by describing in detail illustrative embodiments thereof with reference to the attached drawings, in which:

FIGS. 1, 3, 5, 7, 9, 11 and 13 are plan views illustrating intermediate steps to describe a method for manufacturing a mask pattern according to some embodiments of the present disclosure.

FIGS. 2, 4, 6, 8, 10, 12 and 14 are cross-sectional views taken along lines A-A, B-B and C-C of FIGS. 1, 3, 5, 7, 9, 11 and 13 illustrating intermediate steps to describe a method for manufacturing a mask pattern according to some embodiments of the present disclosure.

FIGS. 15 to 17 are plan views illustrating intermediate steps to describe a method for manufacturing a mask pattern according to some embodiments of the present disclosure.

FIGS. 18, 20, 22 and 24 are plan views illustrating intermediate steps to describe a method for manufacturing a mask pattern according to some embodiments of the present disclosure.

FIGS. 19, 21, 23 and 25-30 are cross-sectional views illustrating intermediate steps to describe a method for manufacturing a mask pattern according to some embodiments of the present disclosure.

### DETAILED DESCRIPTION OF EMBODIMENTS

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from embodiments of the present disclosure.

A method for manufacturing a transistor including a nano-wire or nano-sheet has been shown as a method for manufacturing a semiconductor device according to some embodiments. However, embodiments of the present disclosure are not necessarily limited thereto. Embodiments of the present disclosure may also be applied to a method for manufacturing a fin-type transistor (FinFET) including a channel region of a fin-type pattern shape.

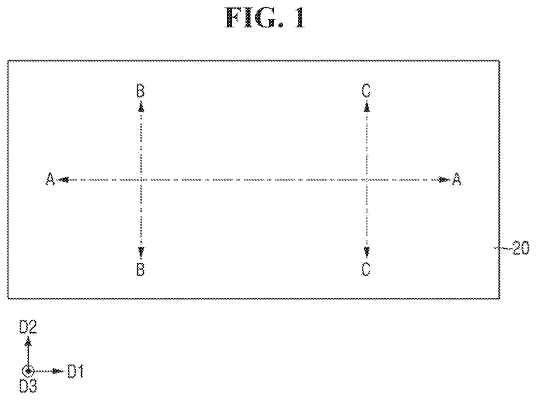

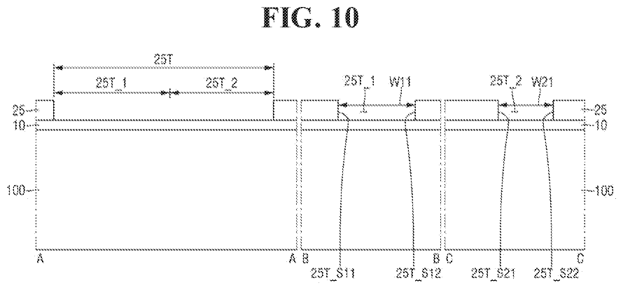

A method for manufacturing a mask pattern according to some embodiments will be described with reference to FIGS. 1 to 14.

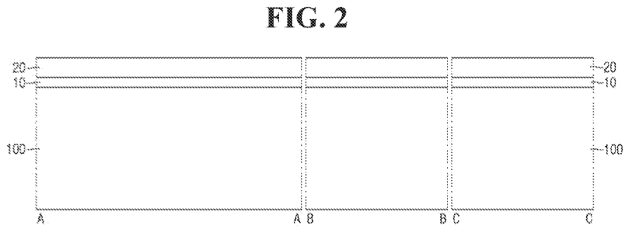

FIGS. 1 to 14 are views illustrating intermediate steps to describe a method for manufacturing a mask pattern according to some embodiments. For reference, FIGS. 1, 3, 5, 7, 9, 11 and 13 are plan views illustrating a method for manufacturing a mask pattern according to some embodiments. FIGS. 2, 4, 6, 8, 10, 12 and 14 are cross-sectional views taken along lines A-A, B-B and C-C of FIGS. 1, 3, 5, 7, 9, 11 and 13.

Referring to FIGS. 1 and 2, a buffer layer 10 may be formed on a substrate 100. For example, in an embodiment the buffer layer 10 may be formed directly on the substrate 100 in a third direction D3 which is a thickness direction of the substrate 100.

In an embodiment, the substrate 100 may be, for example a silicon substrate, a bulk silicon or a silicon-on-insulator (SOI). In an embodiment, the substrate 100 may include an element semiconductor such as germanium, or a compound semiconductor such as a group IV-IV compound semiconductor or a group III-V compound semiconductor. In an embodiment, the substrate 100 may be an epitaxial layer formed on a base substrate. In an embodiment, the substrate 100 may be a ceramic substrate, a quartz substrate or a display glass substrate.

In an embodiment, the group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element.

In an embodiment, the group III-V compound semiconductor may be, for example, one of a binary compound, a ternary compound or a quaternary compound, which is formed by combination of at least one of aluminum (Al), gallium (Ga) or indium (In), which is a group III element, and one of phosphorus (P), arsenic (As) and antimony (Sb), which are group V elements.

In the following description, the substrate 100 will be described as being a substrate including a semiconductor material for convenience of description.

In an embodiment, the buffer layer 10 may include at least one of, for example, a silicon-containing material such as silicon oxide, silicon oxynitride, silicon nitride, TetraEthylOthoSilicate (TEOS), polycrystalline silicon or amorphous silicon, a carbon-containing material such as an amorphous carbon layer (ACL) or a spin-on hardmask (SOH), or metal. The buffer layer 10 may be formed by a process such as atomic layer deposition (ALD), chemical vapor deposition (CVD), physical vapor deposition (PVD), or spin coating, and a bake process or a curing process may be added depending on the material.

In an embodiment shown in FIG. 2, the buffer layer 10 is shown as a single layer. However, embodiments of the present disclosure are not necessarily limited thereto.

A mold mask layer 20 may be formed on (e.g., formed directly thereon in the third direction D3) the buffer layer 10. In an embodiment, the mold mask layer 20 may include at least one of, for example, a silicon-containing material, a carbon-containing material or a conductive material including metal. However, embodiments of the present disclosure are not necessarily limited thereto.

For example, in some embodiments the mold mask layer 20 may be formed on the substrate 100 (e.g., formed directly thereon in the third direction D3) without the buffer layer 10.

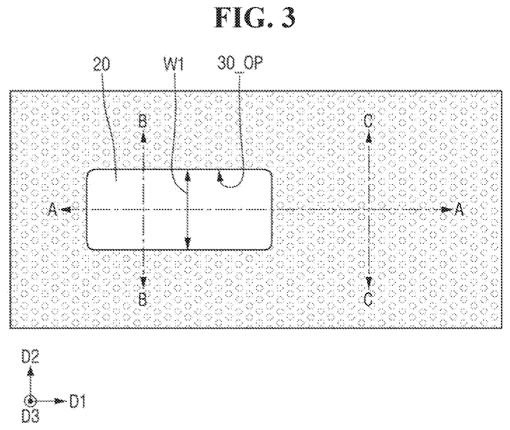

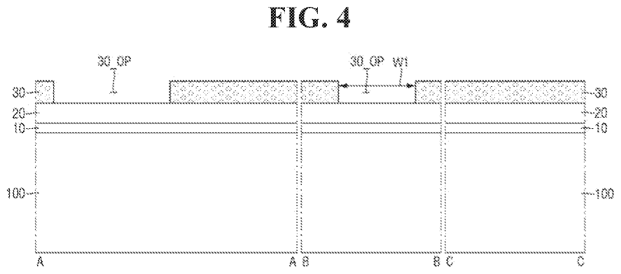

Referring to FIGS. 3 and 4, a first upper mold mask pattern 30 may be formed on (e.g., formed directly thereon in the third direction D3) the mold mask layer 20.

The first upper mold mask pattern 30 may include a first mold opening 30_OP. In an embodiment shown in FIG. 3, an edge of the first mold opening 30_OP is shown as having a rounded shape in a plan view (e.g., in a plane defined in first and second directions D1, D2). However, embodiments of the present disclosure are not necessarily limited thereto.

The first mold opening 30_OP may extend in the first direction D1. The first mold opening 30_OP may have a first mold width W1 in the second direction D2. For example, the second direction D2 may be orthogonal to the first direction D1. However, embodiments of the present disclosure are not necessarily limited thereto and the second direction D2 may cross the first direction D1 in various different angles.

The first upper mold mask pattern 30 may include an upper surface and a lower surface, which are opposite to each other in a third direction D3. The lower surface of the first upper mold mask pattern 30 may face the mold mask layer 20. For example, in an embodiment the lower surface of the first upper mold mask pattern 30 may directly contact an upper surface of the mold mask layer 20. The first mold width W1 of the first mold opening 30_OP may be, for example, a width measured on the upper surface of the first upper mold mask pattern 30.

In an embodiment, the first upper mold mask pattern 30 may include, for example, at least one of a silicon-containing material, a carbon-containing material or a conductive material including metal. However, embodiments of the present disclosure are not necessarily limited thereto.

In an embodiment shown in FIG. 4, the first upper mold mask pattern 30 is shown as being formed directly on the mold mask layer 20. However, embodiments of the present disclosure are not necessarily limited thereto. For example, in an embodiment an additional layer may be formed between the first upper mold mask pattern 30 and the mold mask layer 20 (e.g., in the third direction D3).

Referring to FIGS. 3 to 6, in an embodiment a pre-mold mask pattern 25P may be formed on the substrate 100 by etching the mold mask layer 20.

For example, a portion of the mold mask layer 20 may be etched using the first upper mold mask pattern 30 as an etching mask. The mold mask layer 20 exposed by the first mold opening 30_OP may be etched to form the pre-mold mask pattern 25P.

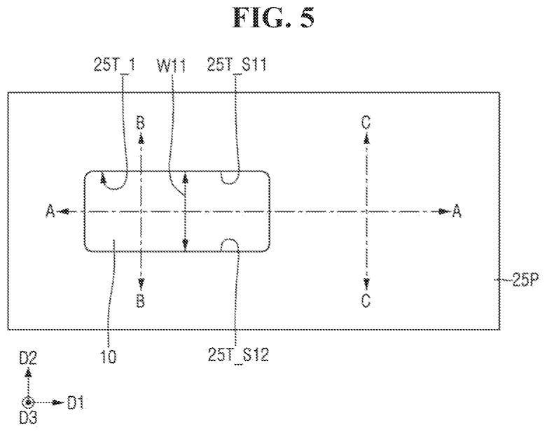

The pre-mold mask pattern 25P may include a first mold trench 25T_1. The first mold trench 25T_1 is formed at a position corresponding to the first mold opening 30_OP of the first upper mold mask pattern 30. In an embodiment shown in FIG. 5, an edge of the first mold trench 25T_1 is shown as having a rounded shape in a plan view (e.g., in a plane defined in the first and second directions D1, D2). However, embodiments of the present disclosure are not necessarily limited thereto.

The first mold trench 25T_1 may extend in the first direction D1. The first mold trench 25T_1 may have a first trench width W11 in the second direction D2. The first mold trench 25T_1 may include a first sidewall 25T_S11 and a second sidewall 25T_S12, which extend in the first direction D1. The first sidewall 25T_S11 of the first mold trench is spaced apart from the second sidewall 25T_S12 of the first mold trench in the second direction D2. For example, in an embodiment, the first mold trench 25T_1 may have a rectangular shape having rounded corners in a plan view with the relatively long sides comprised of the first and second sidewalls 25T_S11, 25T_S12 extending in the first direction D1. However, embodiments of the present disclosure are not necessarily limited thereto.

The pre-mold mask pattern 25P may include an upper surface and a lower surface, which are opposite to each other in the third direction D3. The upper surface of the pre-mold mask pattern 25P may face the first upper mold mask pattern 30. The first trench width W11 of the first mold trench 25T_1 may be, for example, a width measured on the upper surface of the pre-mold mask pattern 25P.

The first upper mold mask pattern 30 may then be removed.

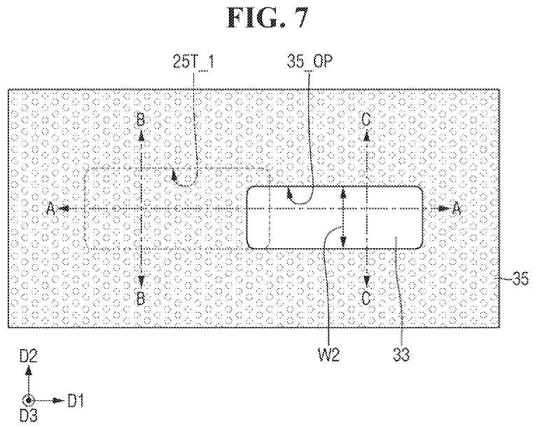

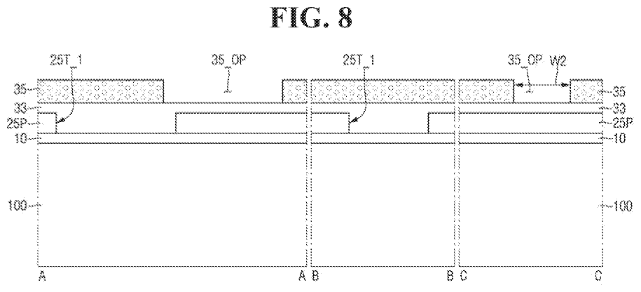

Referring to FIGS. 7 and 8, a second upper mold mask pattern 35 may be formed on the pre-mold mask pattern 25P (e.g., in the third direction D3).

For example, a planarization layer 33 may be formed on (e.g., formed directly thereon in the third direction D3) the pre-mold mask pattern 25P. The planarization layer 33 may fill the first mold trench 25T_1 and extend above the first mold trench 25T_1. In an embodiment, the planarization layer 33 may include, for example, at least one of a silicon-containing material and a carbon-containing material.

The second upper mold mask pattern 35 may be formed on (e.g., formed directly thereon in the third direction D3) the planarization layer 33. The second upper mold mask pattern 35 may include a second mold opening 35_OP. In an embodiment shown in FIG. 7, an edge of the second mold opening 35_OP in a plan view is shown as having a rounded shape. However, embodiments of the present disclosure are not necessarily limited thereto.

The second mold opening 35_OP may extend in the first direction D1. The second mold opening 35_OP may have a second mold width W2 in the second direction D2. The second mold width W2 of the second mold opening 35_OP may be different from the first mold width W1 of the first mold opening (30_OP in FIG. 3). For example, in an embodiment shown in FIG. 7, the second mold width W2 of the second mold opening 35_OP is less than the first mold width W1 of the first mold opening 30_OP. However, embodiments of the present disclosure are not necessarily limited thereto. The second mold width W2 of the second mold opening 35_OP may be, for example, a width measured on the upper surface of the second upper mold mask pattern 35.

The second mold opening 35_OP may overlap a portion of the first mold trench 25T_1 in the third direction D3. In an embodiment, one of sidewalls of the second mold opening 35_OP extending in the first direction D1 may be aligned in the first direction D1 with one of sidewalls of the first mold trench 25T_1 extending in the first direction D1. For example, as shown in FIG. 7 the lower sidewalls (e.g., in the second direction D2) of the first mold trench 25T_1 and the second mold opening 35_OP are aligned with each other. However, embodiments of the present disclosure are not necessarily limited thereto.

In an embodiment, the second upper mold mask pattern 35 may include at least one of, for example, a silicon-containing material, a carbon-containing material or a conductive material including metal. However, embodiments of the present disclosure are not necessarily limited thereto.

Referring to FIGS. 7 to 10, the mold mask pattern 25 may be formed on the substrate 100 by etching the pre-mold mask pattern 25P.

For example, a portion of the pre-mold mask pattern 25P may be etched using the second upper mold mask pattern 35 as an etching mask. The pre-mold mask pattern 25P exposed by the second mold opening 35_OP may be etched to form the mold mask pattern 25.

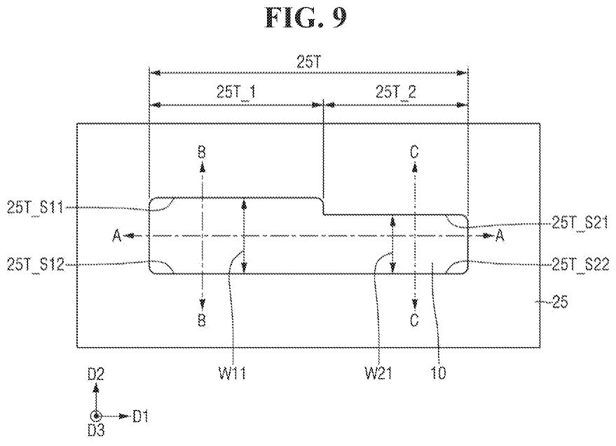

While the pre-mold mask pattern 25P is being etched using the second upper mold mask pattern 35 as an etching mask, a second mold trench 25T_2 connected to the first mold trench 25T_1 may be formed. In an embodiment as shown in FIG. 9, the second mold trench 25T_2 is adjacent to the first mold trench 25T_I in the first direction D1. The second mold trench 25T_2 is formed at a position corresponding to (e.g., overlapping in the third direction D3) the second mold opening 35_OP of the second upper mold mask pattern 35.

The second mold trench 25T_2 may have a second trench width W21 in the second direction D2. The second trench width W21 of the second mold trench 25T_2 may be different from the first trench width W11 of the first mold trench 25T_1. For example, in an embodiment as shown in FIG. 9, the second trench width W21 of the second mold trench 25T_2 is less than the first trench width W11 of the first mold trench 25T_1. However, embodiments of the present disclosure are not necessarily limited thereto.

The mold mask pattern 25 may include an upper surface and a lower surface, which are opposite to each other in the third direction D3. The upper surface of the mold mask pattern 25 may face the second upper mold mask pattern 35. The second trench width W21 of the second mold trench 25T_2 may be, for example, a width measured on the upper surface of the mold mask pattern 25.

The second mold trench 25T_2 includes a first sidewall 25T_S21 and a second sidewall 25T_S22, which extend in the first direction D1. The first sidewall 25T_S21 of the second mold trench is spaced apart from the second sidewall 25T_S22 of the second mold trench in the second direction D2.

The mold mask pattern 25 may include a first mold trench 25T_1 and a second mold trench 25T_2, which are connected to each other. The mold mask pattern 25 may include a connection trench 25T extending in the first direction D1. The connection trench 25T may include the first mold trench 25T_1 and the second mold trench 25T_2.

The second upper mold mask pattern 35 and the planarization layer 33 are then removed.

In an embodiment, the first sidewall 25T_S11 of the first mold trench is closer to (e.g., in the second direction D2) the first sidewall 25T_S21 of the second mold trench than the second sidewall 25T_S12 of the first mold trench. The second sidewall 25T_S12 of the first mold trench is closer to (e.g., in the second direction D2) the second sidewall 25T_S22 of the second mold trench than the first sidewall 25T_SI 1 of the first mold trench.

The first sidewall 25T_S11 of the first mold trench is connected to the first sidewall 25T_S21 of the second mold trench. The second sidewall 25T_S12 of the first mold trench is connected to the second sidewall 25T_S22 of the second mold trench.

For example, the first sidewall 25T_S11 of the first mold trench may not be aligned with the first sidewall 25T_S21 of the second mold trench in a straight line along the first direction D1. For example, the first sidewall 25T_S11 of the first mold trench extending in the first direction D1 may be offset in the second direction D2 from the first sidewall 25T_S21 of the second mold trench that extends in the first direction D1. In an embodiment, the second sidewall 25T_S12 of the first mold trench may be aligned with the second sidewall 25T_S22 of the second mold trench in a straight line along the first direction D1.

In an embodiment, the edge of the first mold trench 25T_l may have a rounded shape in a plan view at a portion adjacent to the first sidewall 25T_S21 of the second mold trench. A portion of the first sidewall 25T_S21 of the second mold trench, which is connected to the first mold trench 25T_1, may not have a rounded shape.

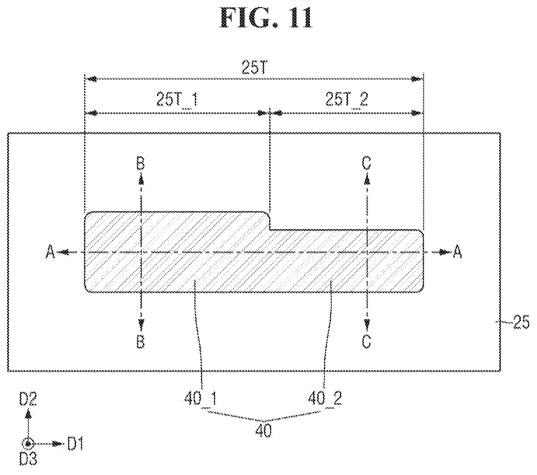

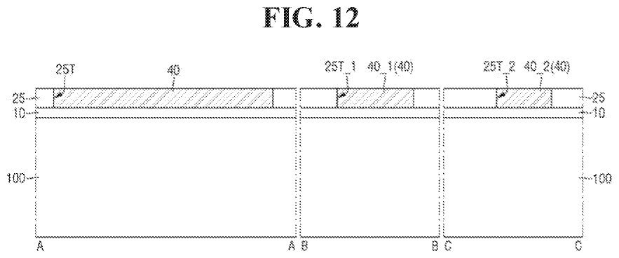

Referring to FIGS. 11 and 12, a process mask pattern 40 may be formed in the mold mask pattern 25.

The process mask pattern 40 may fill the connection trench 25T. In an embodiment, the process mask pattern 40 may be disposed on the substrate 100 and may directly contact an upper surface of the buffer layer 10. The process mask pattern 40 may fill the first mold trench 25T_1 and the second mold trench 25T_2.

The process mask pattern 40 may include a first portion 40_1 and a second portion 40_2. The first portion 40_1 of the process mask pattern may be formed in the first mold trench 25T_1. The second portion 40_2 of the process mask pattern may be formed in the second mold trench 25T_2.

In an embodiment, the process mask pattern 40 may include at least one of, for example, a silicon-containing material, a carbon-containing material or a conductive material including a metal. However, embodiments of the present disclosure are not necessarily limited thereto.

Referring to FIGS. 11 to 14, the mold mask pattern 25 is removed.

As the mold mask pattern 25 is removed, the process mask pattern 40 may remain disposed on the substrate 100. Thus, the process mask pattern 40 is formed on the substrate 100.

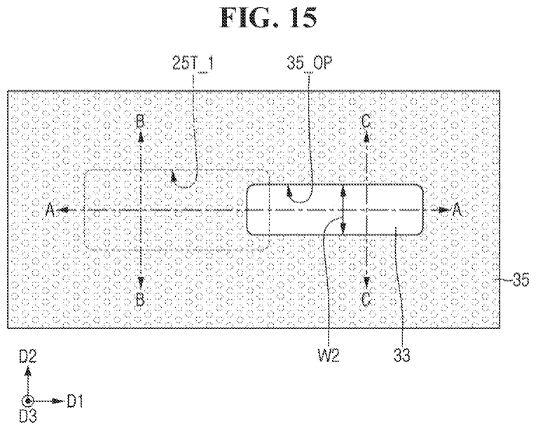

FIGS. 15 to 17 are plan views illustrating intermediate steps to describe a method for manufacturing a mask pattern according to some embodiments. For convenience of description, the following description will be based on differences from those described with reference to FIGS. 1 to 14 and a repeated description of identical or similar elements/steps may be omitted for economy of description.

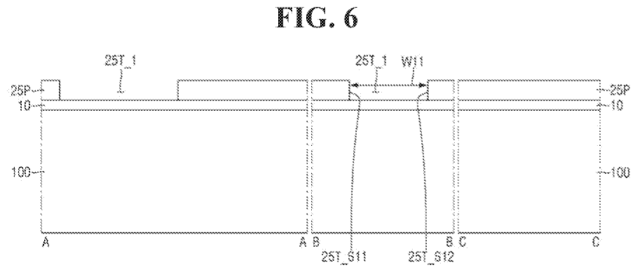

For reference, FIG. 15 may be a manufacturing process performed after FIGS. 5 and 6. In addition, a cross-sectional view taken along lines A-A, B-B and C-C of FIG. 15 may be similar to that of FIG. 8.

Referring to FIG. 15, the second upper mold mask pattern 35 including a second mold opening 35_OP may be formed on the pre-mold mask pattern (25P in FIG. 8).

The sidewall of the second mold opening 35_OP, which extends in the first direction D1, is not aligned in the first direction D1 with that of the first mold trench 25T_1 extending in the first direction D1. For example, each of the sidewalls of the second mold opening 35_OP extending in the first direction D1 may be offset in the second direction D2 from each of the sidewalls of the first mold trench 25T_1 extending in the first direction D1.

Referring to FIGS. 8, 15 and 16, the pre-mold mask pattern 25P may be etched to form the mold mask pattern 25 on the substrate 100.

The mold mask pattern 25 may include a first mold trench 25T_1 and a second mold trench 25T_2, which are connected to each other in the first direction D1.

For example, as shown in an embodiment of FIG. 15 the first sidewall 25T_S11 of the first mold trench may not be aligned with the first sidewall 25T_S21 of the second mold trench in a straight line along the first direction D1. The second sidewall 25T_S12 of the first mold trench is not aligned with the second sidewall 25T_S22 of the second mold trench in a straight line along the first direction D1.

The second upper mold mask pattern 35 is then removed.

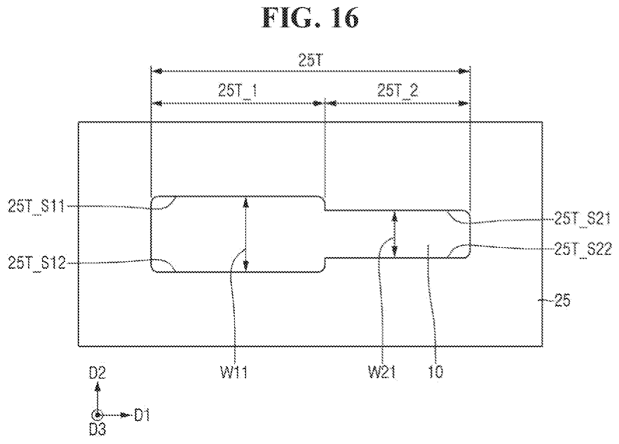

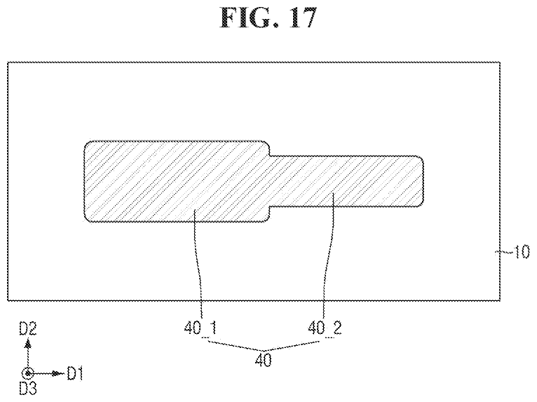

Referring to FIGS. 16 and 17, the process mask pattern 40 filling the first mold trench 25T_1 and the second mold trench 25T_2 is formed.

The mold mask pattern 25 is then removed.

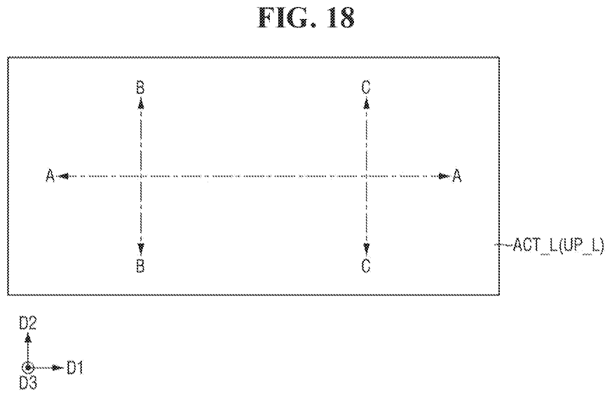

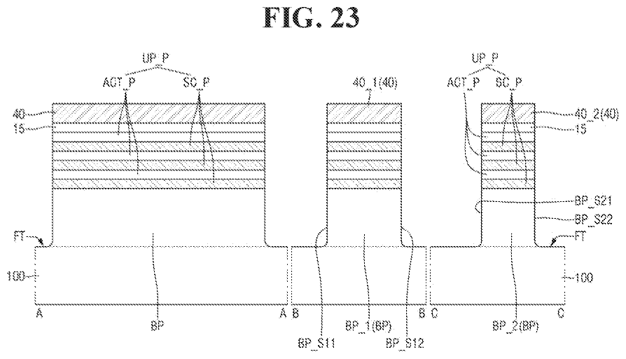

FIGS. 18 to 30 are views illustrating intermediate steps to describe a method for manufacturing a semiconductor device according to some embodiments.

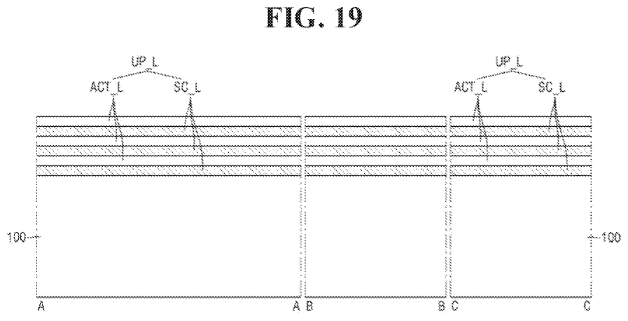

Referring to FIGS. 18 and 19, an upper pattern layer UP_L may be formed on the substrate 100.

In an embodiment, the upper pattern layer UP_L may include a channel layer ACT_L_and a sacrificial layer SC_L, which are alternately stacked on the substrate 100 (e.g., in the third direction D3). In an embodiment, the sacrificial layer SC_L is formed on the substrate 100 (e.g., formed directly thereon in the third direction D3). The channel layer ACT_L is formed on the sacrificial layer SC_L (e.g., formed directly thereon in the third direction D3). The lowermost sacrificial layer SC_L is formed between the substrate 100 and the lowermost channel layer ACT_L (e.g., in the third direction D3).

In an embodiment, the channel layer ACT_L and the sacrificial layer SC_L may be formed on the substrate 100 by using an epitaxial growth method. The channel layer ACT_L may include a material having an etch selectivity with respect to the sacrificial layer SC_L.

In an embodiment, each of the channel layer ACT_L and the sacrificial layer SC_L may include one of silicon or germanium, which is an element semiconductor material, a Group IV-IV compound semiconductor or a Group III-V compound semiconductor. For example, the channel layer ACT_L may include silicon, and the sacrificial layer SC_L may include silicon-germanium. However, embodiments of the present disclosure are not necessarily limited thereto and the material of the layers may vary.

In an embodiment shown in FIG. 19, three sets of channel layers ACT_L and sacrificial layers SC_L are formed on the substrate 100. However, embodiments of the present disclosure are not necessarily limited thereto. In some embodiments, two or four or more sets of channel layers ACT_L and sacrificial layers SC_L may be formed on the substrate 100.

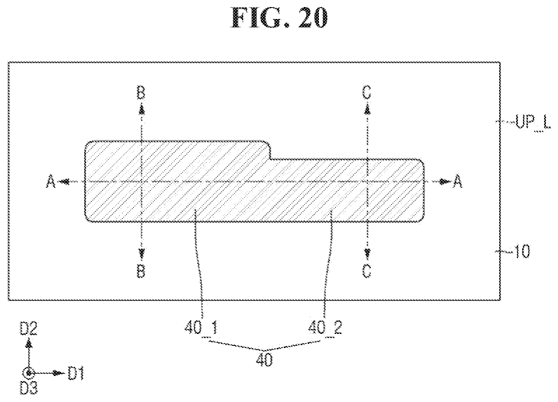

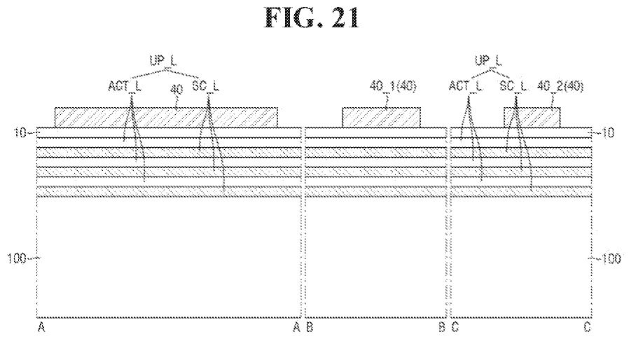

Referring to FIGS. 20 and 21, the buffer layer 10 may be formed on the upper pattern layer UP_L (e.g., formed directly thereon in the third direction D3).

The process mask pattern 40 may be formed on the buffer layer 10 (e.g., formed directly thereon in the third direction D3). The process mask pattern 40 may be formed on the substrate 100. The process mask pattern 40 may be formed on the upper pattern layer UP_L.

For example, the process mask pattern 40 may be formed using the method for manufacturing a mask pattern, which is described with reference to FIGS. 1 to 14. However, embodiments of the present disclosure are not necessarily limited thereto. For example, in an embodiment the process mask pattern 40 may be formed using the method for manufacturing a mask pattern, which is described with reference to FIGS. 1 to 6 and FIGS. 15 to 17.

The mold mask pattern (25 in FIGS. 9 and 16) may be formed on the substrate 100. Subsequently, the process mask pattern 40 may be formed in the mold mask pattern 25. After the process mask pattern 40 is formed, the mold mask pattern 25 may be removed. The method for manufacturing a mask pattern has been described with reference to FIGS. 1 to 17 and thus a repeated description of identical or similar elements/steps will be omitted for economy of description.

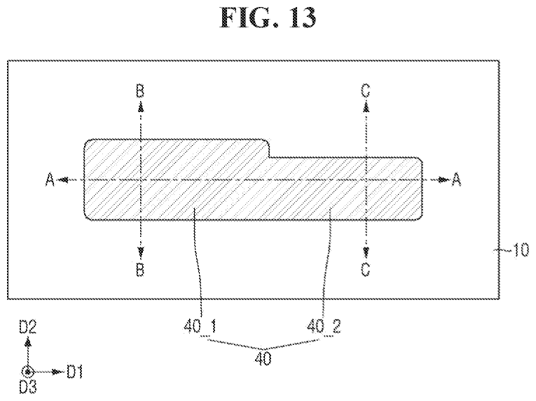

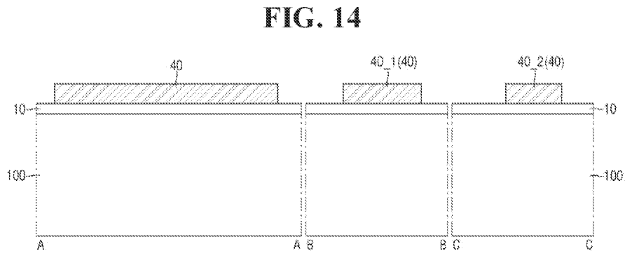

Hereinafter, the process mask pattern 40 will be described as having the shape shown in FIGS. 13 and 14. However, embodiments of the present disclosure are not necessarily limited thereto.

Referring to FIGS. 20 to 23, a lower pattern BP and an upper pattern structure UP_P may be formed on the substrate 100 by using the process mask pattern 40.

A portion of the substrate 100 and the upper pattern layer UP_L may be etched using the process mask pattern 40 as an etching mask. Therefore, the lower pattern BP and the upper pattern structure UP_P may be formed.

The lower pattern BP and the upper pattern structure UP_P may be defined by a fin trench FT. In an embodiment, the lower pattern BP and the upper pattern structure UP_P may extend to be relatively long in the first direction D1. The lower pattern BP may protrude from the substrate 100 in the third direction D3.

The upper pattern structure UP_P may be formed on the lower pattern BP (e.g., formed directly thereon in the third direction D3). The upper pattern structure UP_P may include channel patterns ACT_P and sacrificial patterns SC_P, which are alternately stacked on the lower pattern BP (e.g., in the third direction D3). The channel layer ACT_L is patterned to form the channel pattern ACT_P. The sacrificial layer SC_L is patterned to form the sacrificial pattern SC_P. In an embodiment, the upper pattern structure UP_P may include a relatively long sidewall extending in the first direction D1, and a relatively short sidewall extending in the second direction D2.

While the lower pattern BP and the upper pattern structure UP_P are being formed, the buffer layer 10 may also be etched. The buffer layer 10 is patterned to form a buffer pattern 15.

For example, the lower pattern BP may include a first region BP_1 and a second region BP_2, which are connected to each other in the first direction D1. The first region BP_1 of the lower pattern may be formed at a position corresponding to (e.g., overlapping in the third direction D3) the first portion 40_1 of the process mask pattern. The second region BP_2 of the lower pattern may be formed at a position corresponding to (e.g., overlapping in the third direction D3) the second portion 40_2 of the process mask pattern. For example, the first region BP_1 of the lower pattern may be formed at a position corresponding to the first mold trench (25T_1 in FIG. 9). The second region BP_2 of the lower pattern may be formed at a position corresponding to the second mold trench (25T_2 in FIG. 9).

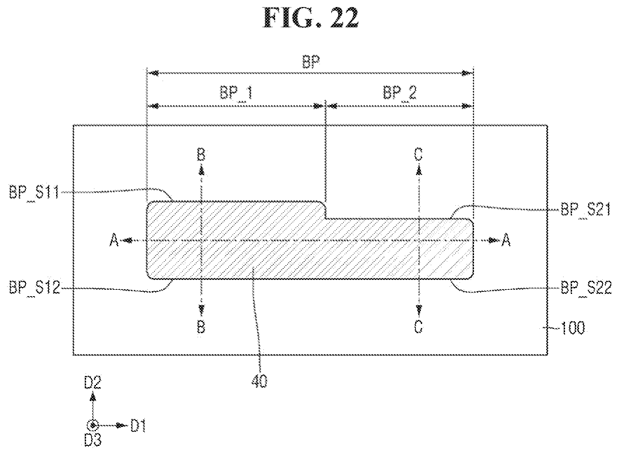

A width of the second region BP_2 of the lower pattern in the second direction D2 may be different from a width of the first region BP_1 of the lower pattern in the second direction D2. For example, in an embodiment as shown in FIG. 22, the width of the first region BP_1 of the lower pattern in the second direction D2 may be greater than the width of the second region BP_2 of the lower pattern in the second direction D2. However, embodiments of the present disclosure are not necessarily limited thereto. For example, a width of the second region BP_2 of the lower pattern in the second direction D2 may be a width measured on an upper surface of the lower pattern BP. The upper surface of the lower pattern BP faces the upper pattern structure UP_P.

The first region BP_1 of the lower pattern includes a first sidewall BP_S11 and a second sidewall BP_S12, which extend in the first direction D1. The first sidewall BP_S11 of the first region of the lower pattern may be opposite to the second sidewall BP_S12 of the first region of the lower pattern in the second direction D2. The first sidewall BP_S11 of the first region of the lower pattern and the second sidewall BP_S12 of the first region of the lower pattern may be defined by the fin trench FT.

The second region BP_2 of the lower pattern includes a first sidewall BP_S21 and a second sidewall BP_S22, which extend in the first direction D1. The first sidewall BP_S21 of the second region of the lower pattern may be opposite to the second sidewall BP_S22 of the second region of the lower pattern in the second direction D2. The first sidewall BP_S21 of the second region of the lower pattern and the second sidewall BP_S22 of the second region of the lower pattern may be defined by the fin trench FT.

The first sidewall BP_S11 of the first region of the lower pattern is closer to the first sidewall BP_S21 of the second region of the lower pattern than the second sidewall BP_S12 of the first region of the lower pattern. The second sidewall BP_S12 of the first region of the lower pattern is closer to the second sidewall BP_S22 of the second region of the lower pattern than the first sidewall BP_S11 of the first region of the lower pattern.

The first sidewall BP_S11 of the first region of the lower pattern is connected to the first sidewall BP_S21 of the second region of the lower pattern. The second sidewall BP_S12 of the first region of the lower pattern is connected to the second sidewall BP_S22 of the second region of the lower pattern.

For example, as shown in an embodiment of FIG. 22 the first sidewall BP_S11 of the first region of the lower pattern may not be aligned with the first sidewall BP_S21 of the second region of the lower pattern in a straight line along the first direction D1. For example, the first sidewall BP_S11 of the first region of the lower pattern extending in the first direction D1 may be offset in the second direction D2 from the first sidewall BP_S21 of the second region of the lower pattern that extends in the first direction D1. The second sidewall BP_S12 of the first region of the lower pattern may be aligned with the second sidewall BP_S22 of the second region of the lower pattern in a straight line along the first direction D1.

However, embodiments of the present disclosure are not necessarily limited thereto. For example, in an embodiment the process mask pattern 40 may have the same shape as that of FIG. 17. In this embodiment, the second sidewall BP_S12 of the first region of the lower pattern may not be aligned with the second sidewall BP_S22 of the second region of the lower pattern in a straight line along the first direction D1.

Referring to FIGS. 22 to 25, a field insulating layer 105 may be formed on (e.g., formed directly thereon in the third direction D3) the substrate 100.

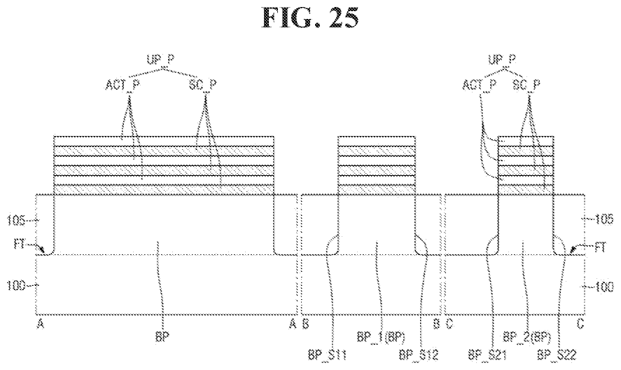

The field insulating layer 105 may fill a portion of the fin trench FT. The field insulating layer 105 may include, for example, an oxide layer, a nitride layer, an oxynitride layer or a combination layer thereof. In an embodiment shown in FIG. 25 the field insulating layer 105 is shown as a single layer. However, but this is only for convenience of description and embodiments of the present disclosure are not necessarily limited thereto.

In an embodiment, at least a portion of the upper pattern structure UP_P may protrude more than the upper surface of the field insulating layer 105 in the third direction D3.

While the field insulating layer 105 is being formed, the process mask pattern 40 and the buffer pattern 15 are removed.

The following description will be made using cross-sectional views taken along lines A-A, B-B and C-C.

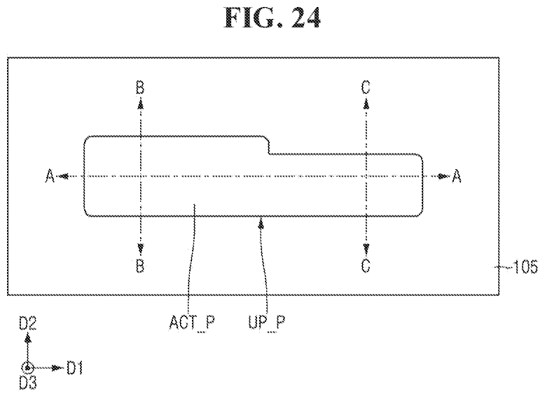

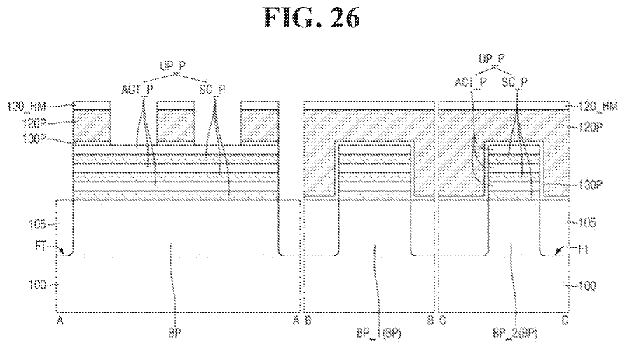

Referring to FIGS. 24 and 26, a dummy gate electrode 120P extending in the second direction D2 may be formed on the upper pattern structure UP_P.

The dummy gate electrode 120P may extend in the first direction D1. A sidewall of the dummy gate electrode 120P is shown as being aligned with the short sidewall of the upper pattern structure UP_P in the third direction D3. However, embodiments of the present disclosure are not necessarily limited thereto.

A dummy gate insulating layer 130P is disposed between the dummy gate electrode 120P and the upper pattern structure UP_P (e.g., in the third direction D3). A dummy gate capping layer 120_HM is disposed on the dummy gate electrode 120P (e.g., disposed directly thereon in the third direction D3). The dummy gate capping layer 120_HM extends along an upper surface of the dummy gate electrode 120P.

In an embodiment, the dummy gate insulating layer 130P may include, for example, silicon oxide. However, embodiments of the present disclosure are not necessarily limited thereto. The dummy gate electrode 120P may include, for example, polysilicon. However, embodiments of the present disclosure are not necessarily limited thereto. The dummy gate capping layer 120_HM may include, for example, silicon nitride. However, embodiments of the present disclosure are not necessarily limited thereto.

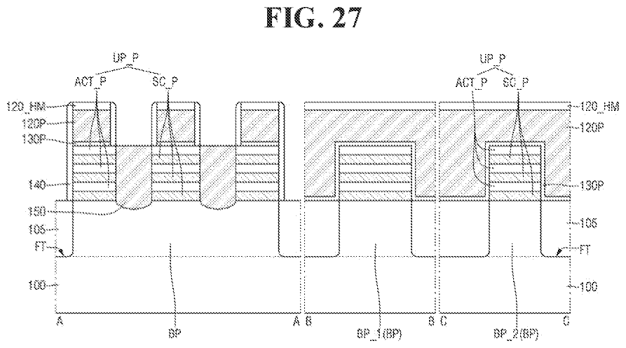

Referring to FIGS. 26 and 27, a gate spacer 140 may be formed on (e.g., formed directly thereon) the sidewall of the dummy gate electrode 120P.

The gate spacer 140 may be formed on (e.g., formed directly thereon) the upper pattern structure UP_P. In an embodiment, the gate spacer 140 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or a combination thereof. The gate spacer 140 is shown as a single layer in an embodiment of FIG. 27 for convenience of description. However, embodiments of the present disclosure are not necessarily limited thereto.

Subsequently, a source/drain pattern 150 may be formed between the dummy gate electrodes 120P adjacent to each other in the first direction D1. The source/drain pattern 150 may be formed on (e.g., formed directly thereon) the lower pattern BP.

The source/drain pattern 150 is connected to the upper pattern structure UP_P. For example, in an embodiment the source/drain pattern 150 may be in direct contact with the channel pattern ACT_P and the sacrificial pattern SC_P.

However, embodiments of the present disclosure are not necessarily limited thereto. For example, in an embodiment the source/drain pattern 150 may be in direct contact with the channel pattern ACT_P, but may not be in direct contact with the sacrificial pattern SC_P. Before the source/drain pattern 150 is formed, a source/drain recess may be formed in the upper pattern structure UP_P. After the source/drain recess is formed, a portion of the sacrificial pattern SC_P may be removed. An inner spacer may then be formed at a position from which a portion of the sacrificial pattern SC_P is removed. In this embodiment, the sacrificial pattern SC_P is not in direct contact with the source/drain pattern 150.

In an embodiment, the source/drain pattern 150 may include, for example, silicon or germanium, which is an element semiconductor material. The source/drain pattern 150 may include a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element. For example, the source/drain pattern 150 may include, but is not necessarily limited to, silicon, silicon-germanium, silicon carbide or the like.

The source/drain pattern 150 may include impurities doped in a semiconductor material. For example, the source/drain pattern 150 includes, for example, n-type impurities. The doped impurities may include at least one of phosphorus (P), arsenic (As), antimony (Sb) or bismuth (Bi). However, embodiments of the present disclosure are not necessarily limited thereto. For example, in an embodiment the source/drain pattern 150 may include p-type impurities. The doped impurities may include at least one of boron (B) or gallium (Ga).

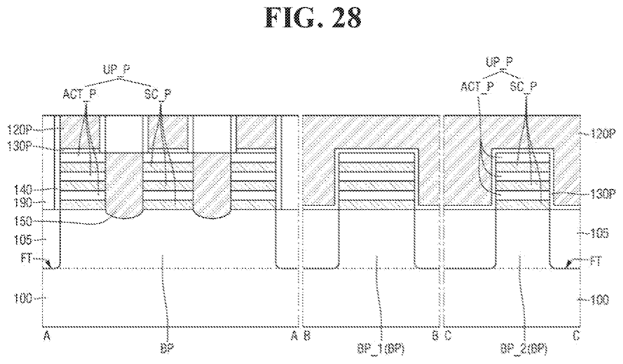

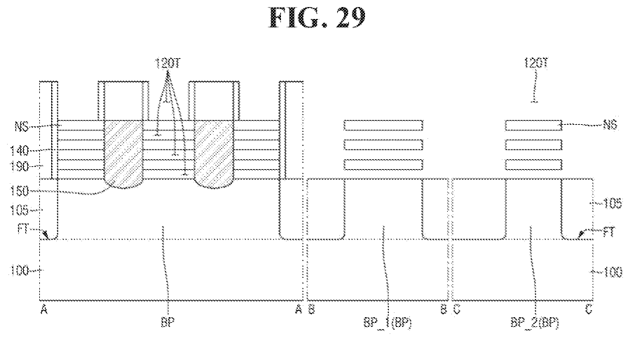

Referring to FIGS. 28 and 29, an interlayer insulating layer 190 is formed on the source/drain pattern 150.

Subsequently, a portion of the interlayer insulating layer 190 and the dummy gate capping layer 120_HM are removed to expose the upper surface of the dummy gate electrode 120P. In an embodiment, a portion of the gate spacer 140 may be removed while the upper surface of the dummy gate electrode 120P is being exposed.

In an embodiment, the interlayer insulating layer 190 may include at least one of, for example, silicon oxide, silicon nitride, silicon oxynitride or a low-k material. The low-k material may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or a combination thereof. However, embodiments of the present disclosure are not necessarily limited thereto.

Referring to FIGS. 28 and 29, the dummy gate insulating layer 130P and the dummy gate electrode 120P may be removed to expose the upper pattern structure UP_P between the gate spacers 140.

Subsequently, a sheet pattern NS may be formed by removing the sacrificial pattern SC_P. The sheet pattern NS is in direct contact with, and is directly connected to, the source/drain pattern 150. Further, a gate trench 120T is formed between the gate spacers 140.

The sheet pattern NS may be formed on the lower pattern BP. The sheet pattern NS may be spaced apart from the lower pattern BP in the third direction D3.

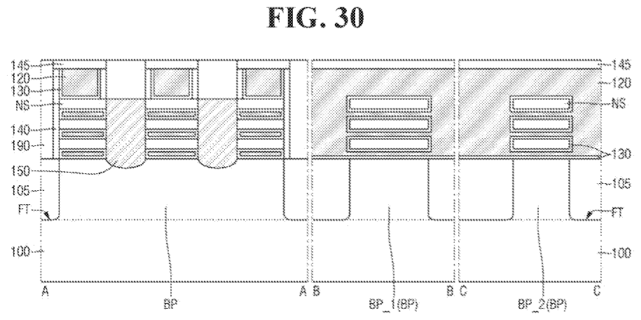

Referring to FIG. 30, a gate insulating layer 130 and a gate electrode 120 may be formed in the gate trench 120T. In addition, a gate capping pattern 145 may be formed.

The gate electrode 120 may be disposed on the lower pattern BP (e.g., in the third direction D3). The gate electrode 120 may cross the lower pattern BP. The gate electrode 120 may surround the sheet pattern NS.

In an embodiment, the gate electrode 120 may include at least one of metal, a metal alloy, a conductive metal nitride, a metal silicide, a doped semiconductor material, a conductive metal oxide or a conductive metal oxynitride. The gate electrode 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAlCN), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. However, embodiments of the present disclosure are not necessarily limited thereto. In an embodiment, the conductive metal oxide and the conductive metal oxynitride may include an oxidized form of the above-described materials. However, embodiments of the present disclosure are not necessarily limited thereto.

The gate insulating layer 130 may extend along an upper surface of the field insulating layer 105 and the upper surface of the lower pattern BP. The gate insulating layer 130 may surround a plurality of sheet patterns NS. For example, the gate insulating layer 130 may be disposed along the periphery of the sheet pattern NS to conformally surround the plurality of sheet patterns NS. The gate electrode 120 is disposed on (e.g., disposed directly thereon) the gate insulating layer 130. The gate insulating layer 130 is disposed between the gate electrode 120 and the sheet pattern NS.

In an embodiment, the gate insulating layer 130 may include silicon oxide, silicon oxynitride, silicon nitride or a high-k material having a dielectric constant higher than that of silicon oxide. The high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate.

The gate insulating layer 130 is shown as a single layer in an embodiment of FIG. 30 for convenience of description. However, embodiments of the present disclosure are not necessarily limited thereto and the gate insulating layer 130 may include a plurality of layers. The gate insulating layer 130 may include an interfacial layer disposed between the sheet pattern NS and the gate electrode 120 and between the lower pattern BP and the gate electrode 120, and a high dielectric constant layer. For example, the interfacial layer may not be formed along a profile of the upper surface of the field insulating layer 105.

The semiconductor device according to some embodiments may include a negative capacitance (NC) FET based on a negative capacitor. For example, the gate insulating layer 130 may include a ferroelectric material layer having ferroelectric characteristics. However, embodiments of the present disclosure are not necessarily limited thereto. For example, in an embodiment the gate insulating layer 130 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is reduced more than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. In an embodiment, the ferroelectric material layer may include at least one of, for example, hafnium oxide, hafnium zirconium oxide, barium strontium titanium oxide, barium titanium oxide, or lead zirconium titanium oxide. In this embodiment, for example, the hafnium zirconium oxide may be a material doped with zirconium (Zr) in hafnium oxide. However, embodiments of the present disclosure are not necessarily limited thereto. For example, in an embodiment the hafnium zirconium oxide may be a compound of hafnium (Hf) and zirconium (Zr) and oxygen (O).

The ferroelectric material layer may further include a doped dopant. For example, in an embodiment the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

In an embodiment in which the ferroelectric material layer includes hafnium oxide, the dopant included in the ferroelectric material layer may include at least one of gadolinium (Gd), silicon (Si), zirconium (Zr), aluminum (Al), or yttrium (Y).

In an embodiment in which the dopant is aluminum (Al), the ferroelectric material layer may include aluminum in a range of about 3 at % to about 8 at % (atomic %). In this embodiment, a ratio of the dopant may be a ratio of aluminum to a sum of hafnium and aluminum.

In an embodiment in which the dopant is silicon (Si), the ferroelectric material layer may include silicon in a range of about 2 at % to about 10 at %. In an embodiment in which the dopant is yttrium (Y), the ferroelectric material layer may include yttrium in a range of about 2 at % to about 10 at %. In an embodiment in which the dopant is gadolinium (Gd), the ferroelectric material layer may include gadolinium in a range of about 1 at % to about 7 at %. In an embodiment in which the dopant is zirconium (Zr), the ferroelectric material layer may include zirconium in a range of about 50 at % to about 80 at %.

The paraelectric material layer may have paraelectric characteristics. In an embodiment, the paraelectric material layer may include at least one of, for example, silicon oxide or metal oxide having a high dielectric constant. The metal oxide included in the paraelectric material layer may include, but is not necessarily limited to, at least one of hafnium oxide, zirconium oxide, or aluminum oxide.

The ferroelectric material layer and the paraelectric material layer may include the same material. Although the ferroelectric material layer has ferroelectric characteristics, the paraelectric material layer may not have ferroelectric characteristics. For example, in an embodiment in which the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. In an embodiment, the thickness of the ferroelectric material layer may be, for example, in a range of about 0.5 nm to about 10 nm. However, embodiments of the present disclosure are not necessarily limited thereto. Since a threshold thickness indicating ferroelectric characteristics may be varied depending on each ferroelectric material, the thickness of the ferroelectric material layer may be varied depending on the ferroelectric material.

For example, the gate insulating layer 130 may include one ferroelectric material layer. For another example, the gate insulating layer 130 may include a plurality of ferroelectric material layers spaced apart from each other. The gate insulating layer 130 may have a stacked layer structure in which a plurality of ferroelectric material layers and a plurality of paraelectric material layers are alternately stacked (e.g., in the third direction D3).

The gate capping pattern 145 may be disposed on (e.g., disposed directly thereon in the third direction D3) the gate electrode 120 and the gate spacer 140. An upper surface of the gate capping pattern 145 may be coplanar (e.g., in the third direction D3) with that of the interlayer insulating layer 190.

However, embodiments of the present disclosure are not necessarily limited thereto. For example, in an embodiment, the gate capping pattern 145 may be disposed between the gate spacers 140.

In an embodiment, the gate capping pattern 145 may include at least one of, for example, silicon nitride (SiN), silicon oxynitride (SiON), silicon carbonitride (SiCN), silicon oxycarbonitride (SiOCN), or a combination thereof. The gate capping pattern 145 may include a material having an etch selectivity with respect to the interlayer insulating layer 190.

In concluding the detailed description, those skilled in the art will appreciate that many variations and modifications may be made to the described embodiments without departing from the principles of the present disclosure. Therefore, the described embodiments of the present disclosure are used in a generic and descriptive sense only and not for purposes of limitation.

What is claimed is:

1. A method for manufacturing a mask pattern, the method comprising:
forming a mold mask layer on a substrate;
forming a pre-mold mask pattern that includes a first trench extending in a first direction, by etching the mold mask layer, the first trench having a first width in a second direction crossing the first direction;
forming a mold mask pattern that includes a second trench connected to the first trench, by etching the pre-mold mask pattern, the second trench having a second width different from the first width in the second direction, the second trench is adjacent to the first trench in the first direction;
forming a process mask pattern in the mold mask pattern that fills the first trench and the second trench, the process mask pattern is disposed on the substrate; and
removing the mold mask pattern, wherein the process mask pattern remains disposed on the substrate after removing the mold mask pattern.

2. The method of claim 1, wherein:
the forming of the mold mask pattern includes forming an upper mold mask pattern on the pre-mold mask pattern, the upper mold mask pattern including a mold opening, and etching the pre-mold mask pattern by using the upper mold mask pattern; and
the mold opening overlaps a portion of the first trench in a third direction that is a thickness direction of the substrate.

3. The method of claim 1, wherein the forming of the pre-mold mask pattern includes forming an upper mold mask pattern on the mold mask layer, the upper mold mask pattern including a mold opening, and etching the mold mask layer by using the upper mold mask pattern.

4. The method of claim 1, wherein:
each of the first trench and the second trench includes a first sidewall extending in the first direction;
the first sidewall of the first trench is connected to the first sidewall of the second trench; and
the first sidewall of the first trench is not aligned with the first sidewall of the second trench in a straight line extending along the first direction.

5. The method of claim 4, wherein:
each of the first trench and the second trench includes a second sidewall extending in the first direction;
the second sidewall of the first trench is connected to the second sidewall of the second trench; and
the second sidewall of the first trench is aligned with the second sidewall of the second trench in a straight line along the first direction.

6. The method of claim 4, wherein:
each of the first trench and the second trench includes a second sidewall extending in the first direction;
the second sidewall of the first trench is connected to the second sidewall of the second trench; and
the second sidewall of the first trench is not aligned with the second sidewall of the second trench in a straight line along the first direction.

7. A method for manufacturing a semiconductor device, the method comprising:
forming an upper pattern layer on a substrate, the upper pattern layer including at least one channel layer and at least one sacrificial layer that are alternately stacked on the substrate,
forming a mold mask layer on the upper pattern layer,
forming a first upper mold mask pattern on the mold mask layer, the first upper mold mask pattern including a first mold opening extending in a first direction, the first mold opening having a first width in a second direction crossing the first direction;
forming a pre-mold mask pattern that includes a first trench, by etching the mold mask layer using the first upper mold mask pattern;
forming a second upper mold mask pattern on the pre-mold mask pattern, the second upper mold mask pattern including a second mold opening extending in the first direction, the second mold opening having a second width different from the first width in the second direction, the second mold opening overlapping a portion of the first trench in a third direction that is a thickness direction of the substrate;
forming a mold mask pattern that includes a second trench connected to the first trench, by etching the pre-mold mask pattern using the second upper mold mask pattern;
forming a process mask pattern in the mold mask pattern, the process mask pattern fills the first trench and the second trench; and
forming a lower pattern and an upper pattern structure extending in the first direction, by using the process mask pattern,
wherein the lower pattern and the upper pattern structure are formed by etching a portion of the substrate and the upper pattern layer.

8. The method of claim 7, wherein:
the lower pattern includes a first region formed at a position corresponding to the first trench and a second region formed at a position corresponding to the second trench;
each of the first region of the lower pattern and the second region of the lower pattern includes a first sidewall extending in the first direction;
the first sidewall of the first region of the lower pattern is connected to the first sidewall of the second region of the lower pattern; and
the first sidewall of the first region of the lower pattern is not aligned with the first sidewall of the second region of the lower pattern in a straight line along the first direction.

9. The method of claim 8, wherein:
each of the first region of the lower pattern and the second region of the lower pattern includes a second sidewall extending in the first direction,
the second sidewall of the first region of the lower pattern is connected to the second sidewall of the second region of the lower pattern; and
the second sidewall of the first region of the lower pattern is aligned with the second sidewall of the second region of the lower pattern in a straight line along the first direction.

10. The method of claim 7, further comprising removing the mold mask pattern before forming the lower pattern and the upper pattern structure.

11. A method for manufacturing a semiconductor device, the method comprising:
forming an upper pattern layer on a substrate, the upper pattern layer including at least one channel layer and at least one sacrificial layer that are alternately stacked on the substrate;
forming a mold mask pattern on the upper pattern layer, the mold mask pattern including a connection trench extending in a first direction, the connection trench including a first trench having a first width in a second direction crossing the first direction and a second trench having a second width in the second direction;
forming a process mask pattern in the mold mask pattern, the process mask pattern filling the connection trench;
forming a lower pattern and an upper pattern structure that extend in the first direction, by using the process mask pattern as an etching mask after removing the mold mask pattern, the upper pattern structure including at least one channel pattern and at least one sacrificial pattern, that are alternately stacked on the lower pattern;
forming a dummy gate electrode on the upper pattern structure, the dummy gate electrode extending in the second direction;
forming a source/drain pattern on the lower pattern, the source/drain pattern is connected to the at least one channel pattern; and
forming a sheet pattern connected to the source/drain pattern by removing the at least one sacrificial pattern after forming the source/drain pattern.

12. The method of claim 11, wherein the forming of the mold mask pattern includes forming the second trench after forming the first trench.

13. The method of claim 12, wherein:
the forming of the second trench includes forming a pre-mold mask pattern on the upper pattern layer, the pre-mold mask pattern including the first trench,
forming an upper mold mask pattern on the pre-mold mask pattern, the upper mold mask pattern including a mold opening, and
etching the pre-mold mask pattern by using the upper mold mask pattern.

14. The method of claim 13, wherein the mold opening overlaps a portion of the first trench in a third direction that is a thickness direction of the substrate.

15. The method of claim 12, wherein:
the forming of the first trench includes forming a mold mask layer on the upper pattern layer,
forming an upper mold mask pattern on the mold mask layer, the upper mold mask pattern including a mold opening, and
etching the mold mask layer by using the upper mold mask pattern.

16. The method of claim 11, wherein:
each of the first trench and the second trench includes a first sidewall extending in the first direction;
the first sidewall of the first trench is connected to the first sidewall of the second trench; and
the first sidewall of the first trench is not aligned with the first sidewall of the second trench in a straight line along the first direction.

17. The method of claim 16, wherein:
each of the first trench and the second trench includes a second sidewall extending in the first direction;
the second sidewall of the first trench is connected to the second sidewall of the second trench; and
the second sidewall of the first trench is aligned with the second sidewall of the second trench in a straight line along the first direction.

18. The method of claim 16, wherein:
each of the first trench and the second trench includes a second sidewall extending in the first direction;
the second sidewall of the first trench is connected to the second sidewall of the second trench; and
the second sidewall of the first trench is not aligned with the second sidewall of the second trench in a straight line along the first direction.

19. The method of claim 11, wherein the lower pattern and the upper pattern structure are formed by etching a portion of the substrate and the upper pattern layer.

20. The method of claim 11, further comprising forming a gate electrode extending in the first direction and surrounding the sheet pattern.
